(19) United States
(12) Patent Application Publication
(10) Pub. No.: US 2007/0126051 A1
(43) Pub. Date: Jun. 7, 2007

(54) Semiconductor memory device and its manufacturing method

(75) Inventor: Yoshiharu Kanegae, Tokyo (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hitachi, Ltd., Tokyo (JP)

(21) Appl. No.: 11/635,759

(22) Filed: Dec. 6, 2006

(30) Foreign Application Priority Data
Dec. 7, 2005 (JP) 2005-353656

(51) Int. Cl. H01L 29/788

(52) U.S. Cl. 257/316

(57) ABSTRACT

A semiconductor memory device having a stable characteristic and high reliability is achieved with formation of nano-dots with excellent interface stability. Source/drain diffusion layers are formed on a P-type silicon substrate to form a silicon oxide film. On this silicon oxide film, a silicon-rich oxide film is formed in a dot shape. On the silicon-rich oxide film, an interlayer dielectric made of SiO₂ is formed. The silicon-rich oxide film has a property of storing charges in the film and excellent in stability of an interface with a silicon oxide film used for a tunneling dielectric. With this, a semiconductor memory device having a stable characteristic and high reliability is achieved with formation of nano-dots with excellent interface stability.

### CROSS-REFERENCE TO RELATED APPLICATION

The present application claims priority from Japanese patent application No. JP 2005-353656 filed on Dec. 7, 2005, the content of which is hereby incorporated by reference into this application.

### BACKGROUND OF THE INVENTION

The present invention relates to semiconductor memory devices and, in particular, to a technology for a charge storage unit in a semiconductor memory device.

Semiconductor memory devices (semiconductor memories), such as flash memories and EEPROMs, are non-volatile and electrically rewritable, and therefore have been widely used as memories for programs and data in digital electrical appliances, vehicle-mounted controllers, and others.

In such a semiconductor memory, microfabrication of elements are required for increasing the speed and capacity. However, when a silicon oxide film for use in a tunneling dielectric is made thinner through microfabrication, a leakage of charges from a poly-silicon film, which is a charge storage layer (floating gate), is increased, thereby causing degradation in a data retention characteristic.

To keep the data retention characteristic, it has been known that there is a limit to making a tunneling dielectric thinner. Also, at the time of rewriting, hot carriers are injected into the floating gate via the tunneling dielectric, thereby causing degradation in the tunneling dielectric. Under the present circumstances, making the tunneling dielectric thinner is reaching its limit.

To solve the problem mentioned above, research and development of non-volatile memories in various novel schemes have been conducted. One of these memories is a silicon nano-dots memory with poly-silicon being formed in a dot shape in place of a poly-silicon film of the floating gate. Since this silicon nano-dots memory stores electrons in discrete dots, even if an electron leakage path is formed in the tunneling oxide film due to rewriting, only the electrons stored in part of dots pass through, and therefore high reliability can be expected.

It is also expected that, by selectively writing electrons in part of dots, multi-bit information is stored in one memory cell by using a difference in threshold voltage due to a difference in writing region (Non-patent Document 1: S. Tiwari et al., IEEE International Electron Devices Meeting, pp. 521 to 524, 1995).

Furthermore, to overcome the limit of making the thickness of the tunneling dielectric thinner, there are the invention in which a dielectric silicon nitride film is used as a charge storage film instead of using conductive poly-silicon (Patent Document 1: U. S. Pat. No. 6,011,725) and the invention in which silicon nitride is formed in a dot shape (Patent Document 2: Japanese Patent Laid-Open Publication No. 2004-179387)

It has been known that a silicon nitride film has a property of storing charges. Also, the energy level of the stored charges is formed in a band gap of the dielectric, and a leakage of charges tends not to occur due to an energy barrier with respect to the band gap, thereby making it possible to make the thickness of the tunneling dielectric thinner than ever.

### SUMMARY OF THE INVENTION

However, in the conventional technology described above, SiN does not have excellent stability of an interface with silicon oxide (SiO₂), which is a tunneling dielectric. Therefore, there is a possibility of occurrence of, for example, degradation in characteristic due to formation of an interface state and decrease in interface adhesion strength.

An object of the present invention is to provide a semiconductor memory device with formation of nano-dots with excellent interface stability and having a stable characteristic and high reliability.

The inventor of the present invention has reviewed the material configuration of a nano-dots memory, and has noted that a silicon-rich oxide film (SiOx (x<2)) has a property of storing charges in the film and also has excellent stability of an interface with a silicon oxide film for use in a tunneling dielectric.

Furthermore, it has been discovered that a nano-dots memory with excellent interface stability and high reliability can be formed by forming a silicon oxide film in the shape of nano-dots.

Still further, in a method of forming nano-dots, it is preferable that a trench for burying dots be formed on a silicon oxide film through electron beam direct writing or electron beam lithography, and then a silicon-rich oxide film be buried through CVD (Chemical Vapor Deposition).

With this, uniform dots are easily formed.

Also, when germanium is used for a substrate, by using a germanium-rich oxide film (GeOx (x<2)) for a charge storage film, similarly, a semiconductor memory device with high reliability can be manufactured.

According to the present invention, it is possible to achieve a semiconductor memory device with formation of nano-dots with excellent interface stability and having a stable characteristic and high reliability, and to achieve a method of manufacturing such a semiconductor memory device.

### BRIEF DESCRIPTION OF THE DRAWINGS

FIG. 1 is a schematic section view of a memory cell of a nano-dots memory in a semiconductor memory device according to one embodiment of the present invention;

FIG. 2 is a drawing of an exemplary case where isolation layers are added to the example shown in FIG. 1;

FIG. 3 is a drawing of an exemplary case where side walls are added to the example shown in FIG. 2;

FIG. 4 is a drawing of an exemplary case where interlayer dielectrics are added to the example shown in FIG. 3;

FIG. 5 is a drawing of an exemplary case where a source/drain diffusion layer is shared by adjacent memory cells in the example shown in FIG. 4;

FIG. 6 is a drawing for describing a method of manufacturing a memory cell in a nano-dots memory according to the first embodiment;

FIG. 7 is a drawing for describing the method of manufacturing a memory cell in a nano-dots memory according to the first embodiment;

FIG. 8 is a drawing for describing the method of manufacturing a memory cell in a nano-dots memory according to the first embodiment;

FIG. 9 is a drawing for describing the method of manufacturing a memory cell in a nano-dots memory according to the first embodiment;

FIG. 10 is a drawing for describing the method of manufacturing a memory cell in a nano-dots memory according to the first embodiment;

FIG. 11 is a drawing for describing the method of manufacturing a memory cell in a nano-dots memory according to the first embodiment;

FIG. 12 is a drawing for describing the method of manufacturing a memory cell in a nano-dots memory according to the first embodiment;

FIG. 13 is a drawing for describing the method of manufacturing a memory cell in a nano-dots memory according to the first embodiment;

FIG. 14 is a drawing for describing the method of manufacturing a memory cell in a nano-dots memory according to the first embodiment;

FIG. 15 is a drawing for describing the method of manufacturing a memory cell in a nano-dots memory according to the first embodiment;

FIG. 16 is a drawing for describing the method of manufacturing a memory cell in a nano-dots memory according to the first embodiment;

FIG. 17 is a drawing for describing the method of manufacturing a memory cell in a nano-dots memory according to the first embodiment;

FIG. 18 is a drawing for describing the method of manufacturing a memory cell in a nano-dots memory according to the first embodiment; and

FIG. 19 is a drawing for describing the method of manufacturing a memory cell in a nano-dots memory according to the first embodiment.

### DESCRIPTION OF THE PREFERRED EMBODIMENTS

Embodiments of the present invention are described in detail below with reference to the attached drawings.

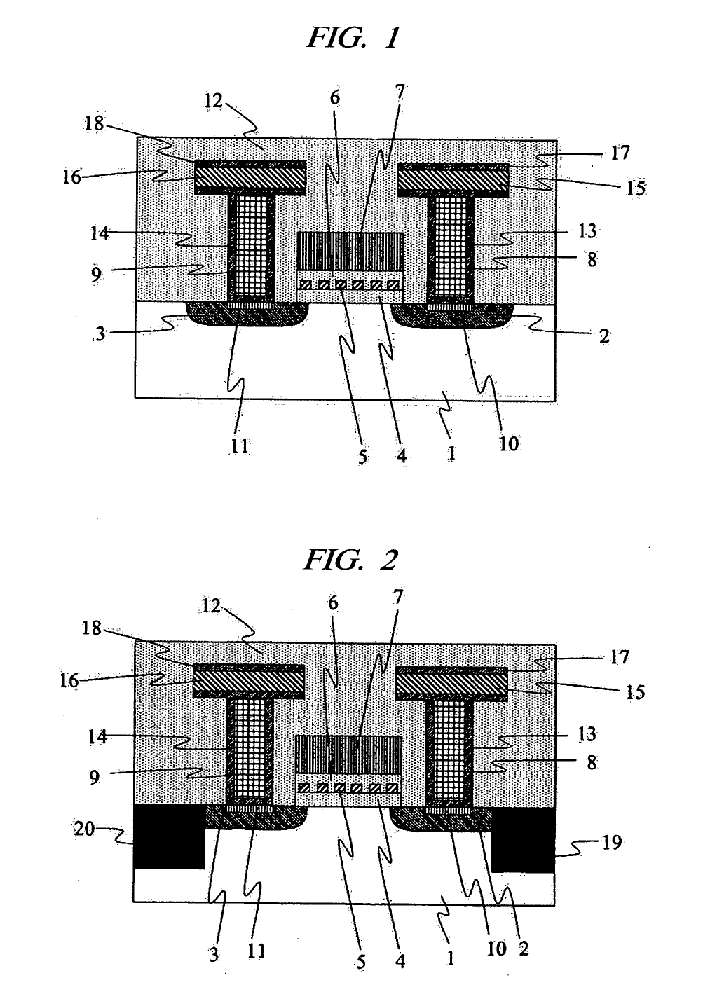

FIG. 1 is a schematic section view of a memory cell of a nano-dots memory in a semiconductor memory device according to one embodiment of the present invention;

In FIG. 1, a P-type silicon substrate 1 has formed thereon source/drain diffusion layers 2 and 3. On the silicon substrate 1, a silicon oxide film 4 is formed. On this silicon oxide film 4, a silicon-rich oxide film 5 is formed in a dot shape. On the dot-shaped silicon-rich oxide film 5, an interlayer dielectric 6 made of SiO₂ is formed. Then, on the interlayer dielectric 6, a control gate 7 is formed.

Dots made of the silicon-rich oxide film 5 are preferably formed by forming a trench for burying dots through electron beam direct writing or electron beam lithography and then burying the silicon-rich oxide film 5 in the trench through CVD. With this, uniform dots can be easily formed.

Also, the silicon substrate 1 may be replaced by a germanium substrate. In this case, the silicon oxide film 4, the silicon-rich oxide film 5, and the interlayer dielectric 6 are replaced by a germanium oxide film, a germanium-rich oxide film, and an interlayer dielectric made of GeO₂, respectively.

Furthermore, since germanium has larger electron mobility than that of silicon, germanium is excellent for increasing the operation speed of the device.

Here, the control gate 7 shown in FIG. 1 is made of, for example, a poly-silicon film, a metal thin film, or a metal silicide film, or has a multilayered configuration with these films. In particular, to suppress interdiffusion at the interface with the gate dielectric 4 and reduce resistance of the gate electrode for increasing the speed, such a configuration is preferable that a thin barrier metal with high adhesion, such as TiN or TaN, be used on the gate dielectric 4 and, on that barrier metal, a metal thin film, such as W, Mo, Ta, or Ti, be used.

In this case, when a low resistance is a matter of concern, W or Mo is used. W has a high melting point and is excellent in thermal stability, whilst Mo is excellent in film planarization.

Also, when adhesion with the barrier metal is a matter of concern, a configuration using Ti on TiN or a configuration using Ta on TaN is used.

Still further, to the source/drain diffusion layers 2 and 3, contact plugs 8 and 9 made of W, Al, poly-Si (poly-silicon), or others, are connected, respectively. However, for adhesion with the interface of the silicon substrate 1, interdiffusion at the interface, and anti-stripping, the contact plugs 8 and 9 are preferably formed after contact layers 10 and 11 are formed at a contact region interface and barrier metals 13 and 14 are formed at an interface between an upper portion of the contact layers 10 and 11 and the interlayer dielectric 12.

The material of the contact layers 10 and 11 is cobalt silicide (CoSi₂), titanium silicide (TiSi₂), or others, whilst the material of the barrier metals 13 and 14 is TiN, TaN, or others.

The contact plugs 8 and 9 are connected to wiring layers 15 and 16, respectively, which are made of Al, Cu, or others. For interdiffusion at the interface and anti-stripping, the wiring layers 15 and 16 preferably have barrier metals 17 and 18, respectively, made of TiN, TaN, or others, above and below each contact plug.

Still further, the memory cell of the nano-dots memory according to one embodiment of the present invention may have isolation layers 19 and 20 made of SiO₂, for example, formed through STI (Shallow Trench Isolation), LOCOS (Local Oxidation of Silicon), or others, as shown in FIG. 2.

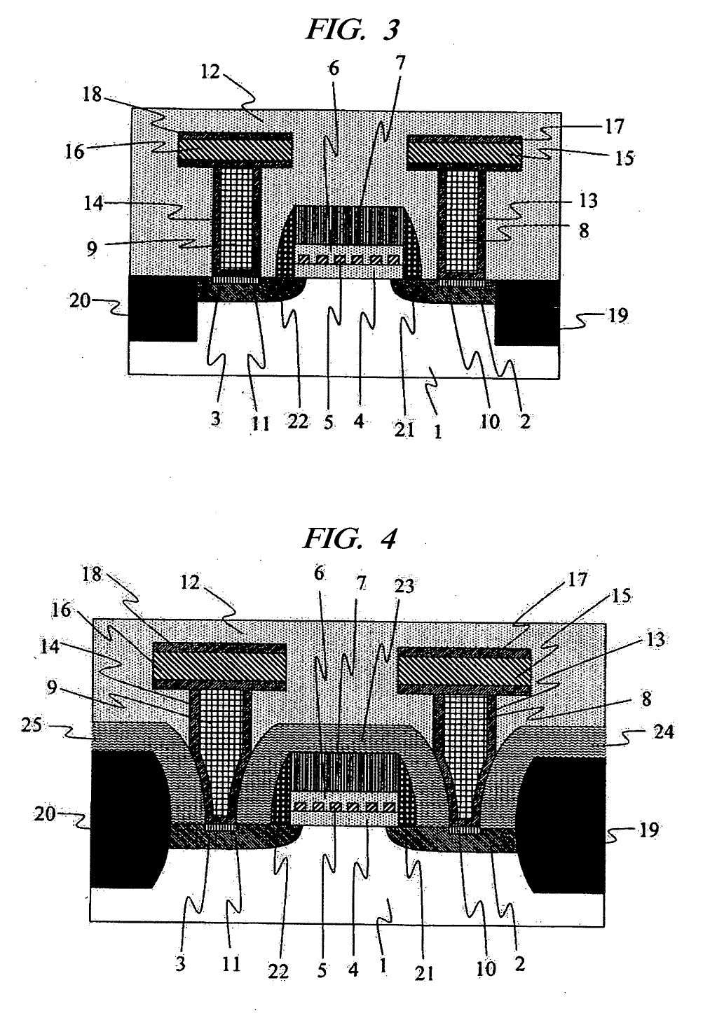

In this case, since dielectric isolation is performed between cells, high integration is possible. Alternatively, as shown in FIG. 3, side walls 21 and 22 made of SiN, SiO₂, or others may be provided. In this case, implantation damage of the dielectrics at the time of forming the source/drain diffusion layers 2 and 3 can be reduced. Furthermore the occurrence of a short channel effect by the diffusion of the impurities at implantation in a channel direction can be suppressed.

Alternatively, as shown in FIG. 4, the contact plugs 8 and 9 may be formed in a self-aligning manner by using the patterns of an interlayer dielectric 23 made of SiN on a transistor and interlayer dielectrics 24 and 25 made of SiN on the isolation layers 19 and 20, respectively.

In this case, there is an advantage of keeping the positions of contact holes correctly even if masks for lithography are slightly out of alignment.

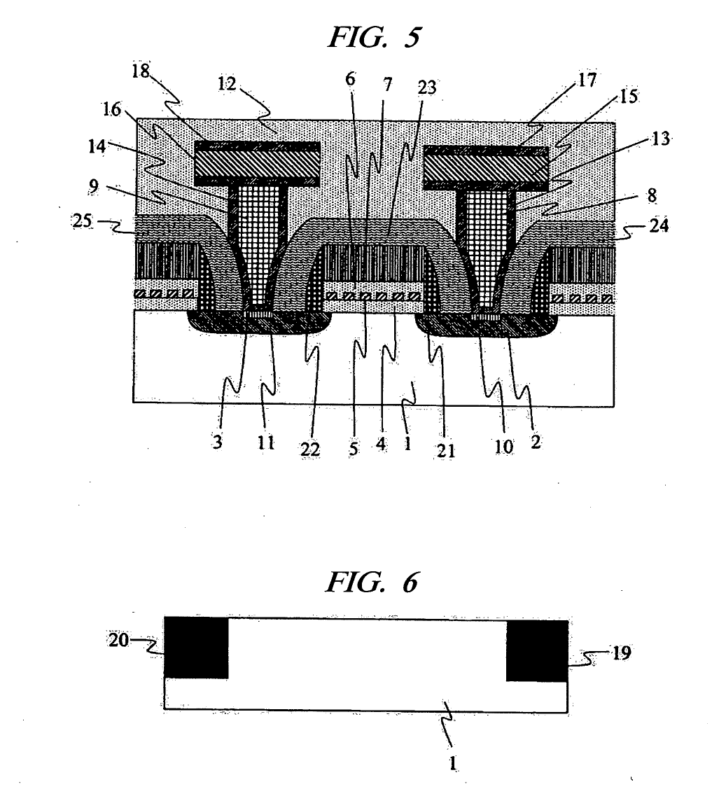

Still alternatively, as shown in FIG. 5, the source/drain diffusion layers 2 and 3 may be commonly used between adjacent memory cells. In this case, since the number of cells per unit area is increased, high integration is possible. Also, with commonality of the source/drain diffusion layers, the configuration is more simplified, thereby reducing manufacturing cost.

In the nano-dots memory according to one embodiment of the present invention, a tunneling dielectric made of SiO₂ (GeO₂) is formed on a silicon (germanium) substrate. Then, a trench for burying dots is formed through electron beam direct writing or electron beam lithography. Then, silicon-rich (germanium-rich) oxide film is buried in the trench through CVD or other schemes.

The silicon-rich oxide film (SiOx (x<2)) (germanium-rich oxide film (GeOx (x<2)) has a property of storing charges in the film, and is excellent in stability of the interface with the silicon oxide film (germanium oxide film) for use in the tunneling dielectric.

Therefore, if a silicon-rich oxide film (germanium-rich oxide film) in a dot shape is formed as a charge storage film, a uniform device with excellent interface stability is formed. Also, with the formation of uniform nano-dots with excellent interface stability, a nano-dots memory with less variations in device characteristic, high reliability, and high yield is manufactured.

Next, a method of manufacturing a memory cell in the nano-dots memory according to the present invention.

Here, for silicon nano-dots memory, to prevent the problem of variations in device characteristic associated with non-uniformity of dots, uniform dot formation is required. However, in silicon deposition through CVD in the conventional technology, uniform dot formation is not an easy task.

The memory cell manufacturing method according to the present invention allows uniform dot formation with ease.

Here, in the following description, a method of manufacturing a memory cell having the configuration shown in FIG. 3 is described.

First, as shown in FIG. 6, isolation layers 19 and 20 are formed on the P-type silicon (germanium) substrate 1 through STI or LOCOS.

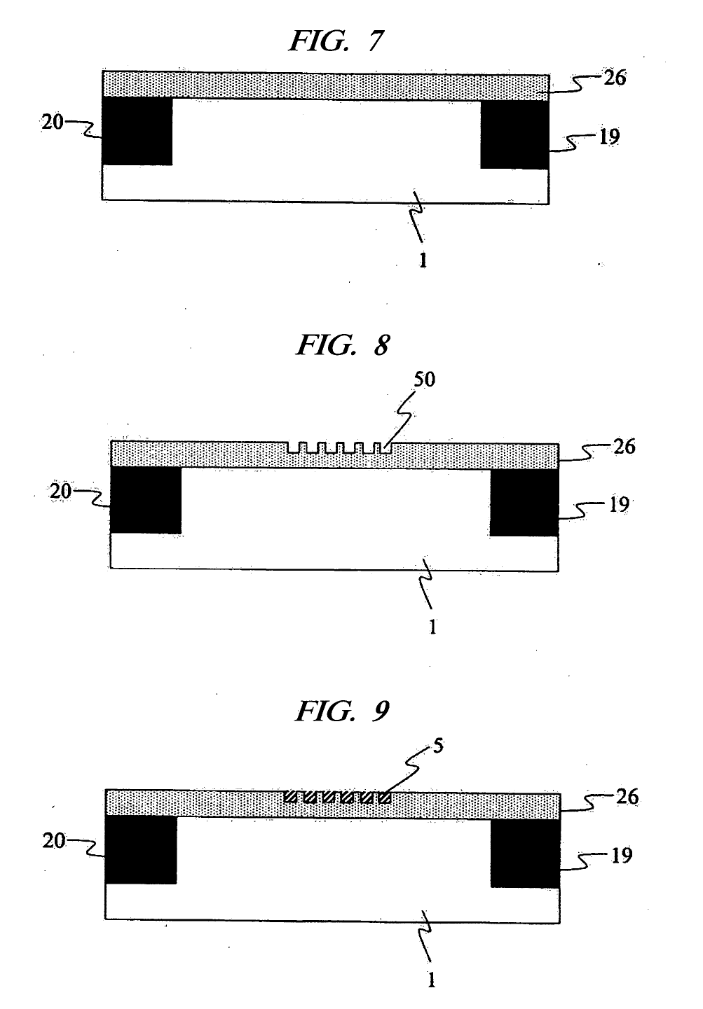

Next, as shown in FIG. 7, a dielectric 26 made of SiO₂ (GeO₂) is formed through thermal oxidation of the substrate or CVD.

Then, as shown in FIG. 8, a trench 50 for burying dots is formed on the dielectric 26 through electron beam direct writing or electron beam lithography.

Next, as shown in FIG. 9, silicon-rich (germanium-rich) oxide film 5 is buried in the trench 50 through CVD or others, and then planarization is performed through CMP (Chemical Mechanical Polishing). At this time, to form a silicon-rich oxide film, for example, the quantity of flow of gas (N₂O, O_{2,} or others) to supply oxygen can be reduced compared with the case of a SiO₂ (GeO₂) formation process through CVD.

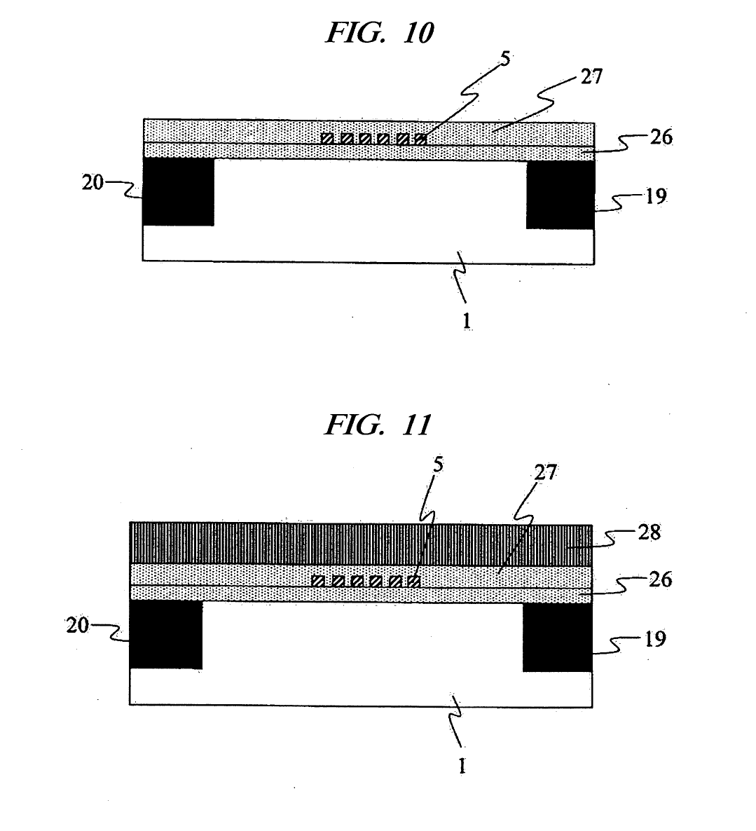

Then, as shown in FIG. 10, an interlayer dielectric 27 made of SiO₂ (GeO₂) is formed on the dielectric 26. Then, as shown in FIG. 11, a poly-silicon film containing impurities of P or B, a metal thin film, a metal silicide film, or a multilayered film of these films 28 is formed through CVD or others for use as a control gate.

Next, as shown in FIG. 12, by using a photoresist film as a mask, a multilayered film is processed by etching so as to has a memory-cell configuration (the silicon oxide film 4, the interlayer dielectric 6, the dots 5, and the control gate 7).

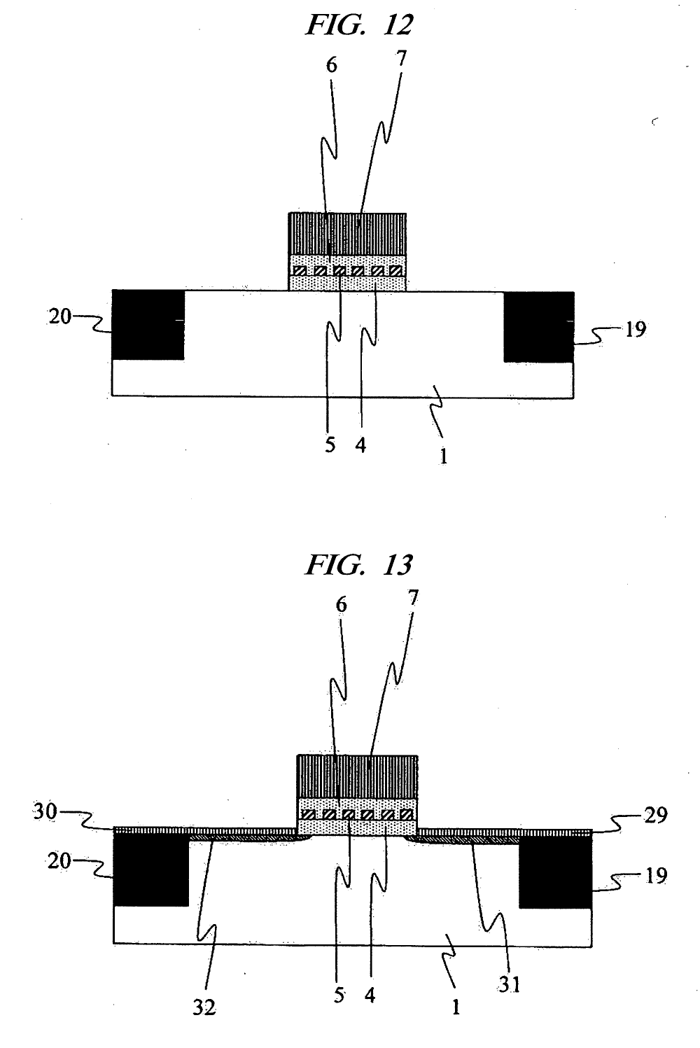

Then, as shown in FIG. 13, SiO₂ or SiN films 29 and 30 having a film thickness on the order of 2 nm are formed through CVD or thermal oxidation. With ion implantation of As or P, shallow source/drain regions 31 and 32 are formed. This process is to form an extension region connecting the source/drain diffusion layers and the channel portion.

An object of forming the SiO₂ or SiN films is to mitigate damage on the substrate due to ion implantation.

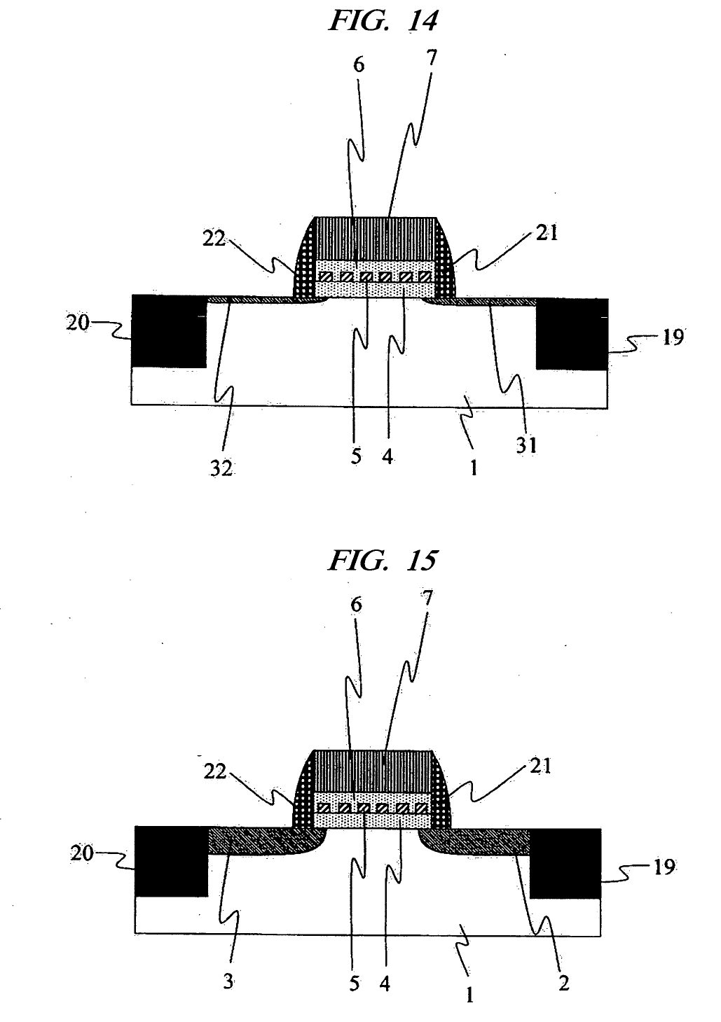

Next, as shown in FIG. 14, after a SiO₂ or SiN film having a film thickness on the order of 200 nm is deposited through spattering or CVD, etching is performed to form the side walls 21 and 22. Then, as shown in FIG. 15, with ion implantation of As or P, the source/drain diffusion layers 2 and 3 are formed.

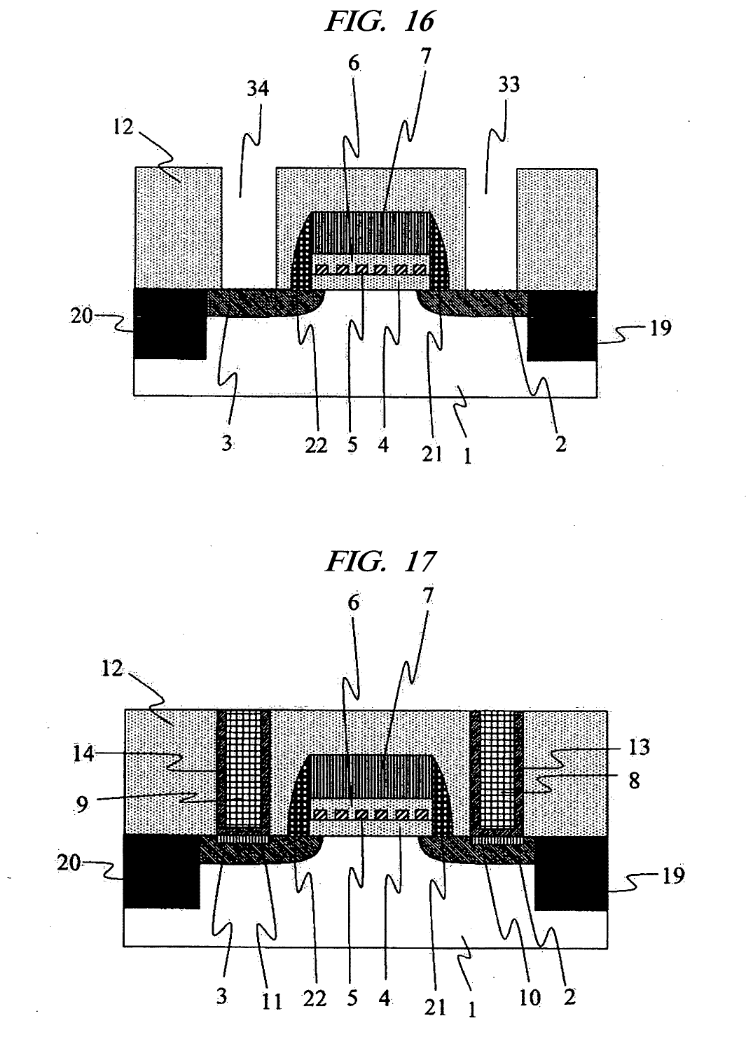

Next, as shown in FIG. 16, after the interlayer dielectric 12 is deposited on the diffusion layers 2 and 3, the control gate 7, and others through CVD or spattering, etching is performed to remove the interlayer dielectric 12 on the source/drain diffusion layers 2 and 3 to form contact hole 33 and 34.

Then, as shown in FIG. 17, Co, Ti, or others is deposited on opening portions of the contact holes 33 and 34 through spattering, and a thermal treatment is performed, thereby forming contact layers 10 and 11 made of CoSi₂, TiSi₂, or others at portions in contact with Si.

Then, Co, Ti, or others at portions in contact with the interlayer dielectric 12 are removed. Then, after barrier metals 13 and 14 made of TiN, TaN, or others are formed through spattering, the contact plugs 8 and 9 are formed through spattering. Then, planarization is performed through CMP.

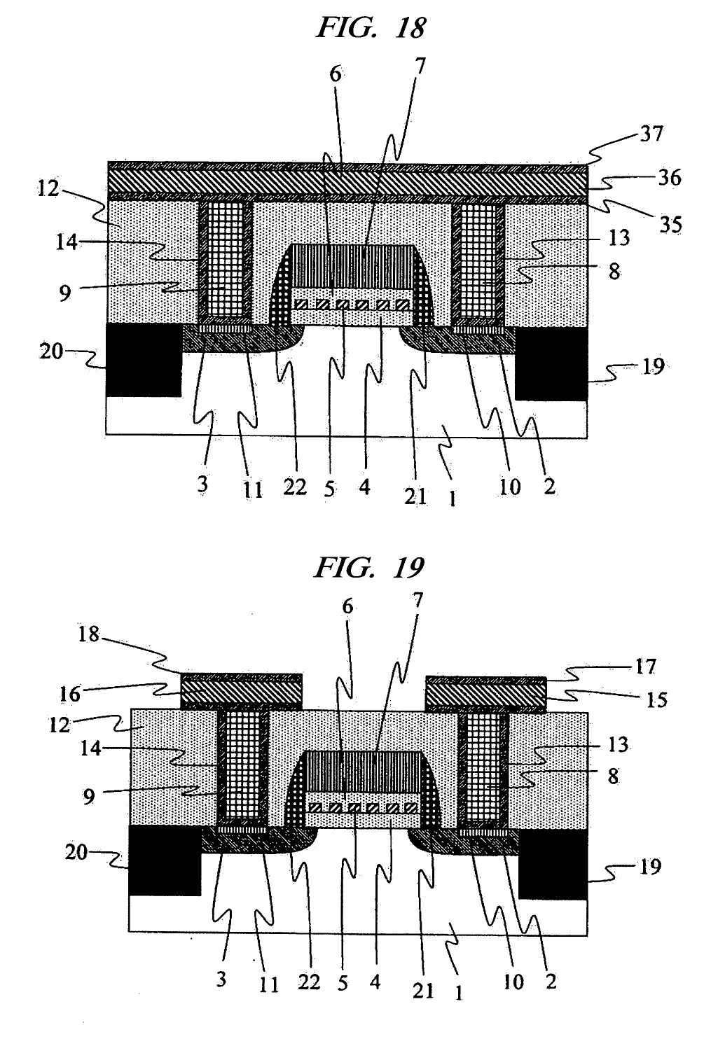

Next, as shown in FIG. 18, a barrier metal 35 made of TiN, TaN, or others, a wiring layer 36 made of Al, Cu, or others, and a barrier metal 37 made of TiN, TaN, or others are deposited through spattering on the interlayer dielectric 12, the contact plugs 8 and 9, and the barrier metals 13 and 14.

Then, as shown in FIG. 19, after planarization through CMP, the barrier metals 35 and 37 and the wiring layer 36 are removed through etching other than regions on the contact plugs 8 and 9, thereby forming wiring layers 15 and 16.

Then, the interlayer dielectric 12 is further deposited, thereby forming a memory cell of a silicide dot memory shown in FIG. 3.

Here, although only one wiring layer is depicted in FIG. 3, one more wiring layer or a plurality of wiring layers may be present above the wiring layer, and these wiring layers may be connected through a via plug made of W, Cu, Al, or the like.

Also, although a P-type substrate is used in the semiconductor memory device manufacturing method described above, this method can be applied to the case of using an N-type substrate.

Furthermore, the semiconductor memory device manufacturing method described above is a method of manufacturing a semiconductor memory device having a memory cell with the configuration shown in FIG. 3, that is, the configuration in which the silicon-rich (germanium-rich) oxide film 5 is formed in a dot shape. However, the semiconductor memory device manufacturing method according to the present invention can be applied to a method of manufacturing a memory cell in which silicon nitride and poly-silicon are formed in a dot shape on a charge storage film.

With the manufacturing method according to the present invention described above, a uniform nano-dots memory with excellent interface stability, high reliability, and high yield is manufactured.

What is claimed is:

1. A semiconductor memory device comprising:
a silicon substrate;
a tunneling gate dielectric formed on the silicon substrate and made of a silicon oxide film;
a charge storage unit formed on the tunneling gate dielectric and having a silicon-rich oxide film in a shape of a plurality of dots; and
a control gate formed on the charge storage unit.

2. A semiconductor memory device comprising:
a germanium substrate;
a tunneling gate dielectric formed on the germanium substrate and made of a germanium oxide film;
a charge storage unit formed on the tunneling gate dielectric having a germanium-rich oxide film in a shape of a plurality of dots; and
a control gate formed on the charge storage unit.

3. A method of manufacturing a semiconductor memory device comprising the steps of:
forming a tunneling gate dielectric by depositing a silicon oxide film on a silicon substrate through thermal oxidation or CVD;
forming a trench for burying dots on the tunneling gate dielectric through electron beam direct writing or electron beam lithography;
forming a charge storage unit having a silicon-rich oxide film in a shape of a plurality of dots by burying a silicon-rich oxide film in the trench for burying dots through CVD;
forming an interlayer dielectric made of a silicon oxide film on the charge storage unit; and
forming a film serving as a control gate on the interlayer dielectric.

4. A method of manufacturing a semiconductor memory device comprising the steps of:
forming a tunneling gate dielectric by depositing a germanium oxide film on a germanium substrate through thermal oxidation or CVD;
forming a trench for burying dots on the tunneling gate dielectric through electron beam direct writing or electron beam lithography;
forming a charge storage unit having a germanium-rich oxide film in a shape of a plurality of dots by burying a germanium-rich oxide film in the trench for burying dots through CVD;
forming an interlayer dielectric made of a germanium oxide film on the charge storage unit; and
forming a film serving as a control gate on the interlayer dielectric.

5. A semiconductor memory device comprising:
a tunneling gate dielectric formed by depositing a silicon oxide film on a silicon substrate through thermal oxidation or CVD;
a charge storage unit having a silicon-rich oxide film in a shape of a plurality of dots formed by forming a trench for burying dots on the tunneling gate dielectric through electron beam direct writing or electron beam lithography and burying a silicon-rich oxide film in the trench for burying dots through CVD;
an interlayer dielectric formed on the charge storage unit and made of a silicon oxide film; and
a control gate formed on the interlayer dielectric.

6. A semiconductor memory device comprising:
a tunneling gate dielectric formed by depositing a germanium oxide film on a germanium substrate through thermal oxidation or CVD;
a charge storage unit having a germanium-rich oxide film in a shape of a plurality of dots formed by forming a trench for burying dots on the tunneling gate dielectric through electron beam direct writing or electron beam lithography and burying a germanium-rich oxide film in the trench for burying dots through CVD;
an interlayer dielectric formed on the charge storage unit and made of a germanium oxide film; and
a control gate formed on the interlayer dielectric.

7. A method of manufacturing a semiconductor memory device comprising the steps of:
forming a tunneling gate dielectric on a substrate through thermal oxidation or CVD;
forming a trench for burying dots on the tunneling gate dielectric through electron beam direct writing or electron beam lithography;
forming a charge storage unit having a shape of a plurality of dots by burying a charge storage film in the trench for burying dots through CVD;
forming an interlayer dielectric on the charge storage unit; and
forming a film serving as a control gate on the interlayer dielectric.
